(19) United States
(12) Patent Application Publication
(10) Pub. No.: US 2024/0071972 A1
(43) Pub. Date: Feb. 29, 2024

(54) SEMICONDUCTOR CONDUCTIVE PILLAR DEVICE AND METHOD

(71) Applicant: Micron Technology, Inc., Boise, ID (US)

(72) Inventors: Hidenori Yamaguchi, Higashihiroshima (JP); Keizo Kawakita, Higashi Hiroshima City (JP); Bang-Ning Hsu, Tainan (TW)

(21) Appl. No.: 17/823,162

(22) Filed: Aug. 30, 2022

(51) Int. Cl. H01L 23/00; H01L 25/065; H01L 25/18

(52) U.S. Cl. CPC H01L 24/14; H01L 24/11; H01L 24/13; H01L 24/16; H01L 25/0657; H01L 25/18; H01L 2224/11464; H01L 2224/11912; H01L 2224/13014; H01L 2224/13016; H01L 2224/13082; H01L 2224/13147; H01L 2224/13155; H01L 2224/1403; H01L 2224/14051; H01L 2224/14134; H01L 2224/14154; H01L 2224/14177; H01L 2224/14181; H01L 2224/16145; H01L 2225/06513; H01L 2924/1431; H01L 2924/1436

(57) ABSTRACT

Apparatus and methods are disclosed, including stacked die devices and systems. Example stacked die devices and methods include an array of interconnect pillars that includes more than one pillar height. Example stacked die devices and methods include an array of interconnect pillars that includes a pillar height distribution mapped to a known warpage profile.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to dies in a stack of dies. Individual dies in a stack of dies can have issues with warpage. Configurations and methods described below address warpage issues and other technical challenges.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1A illustrates a memory device in accordance with some example embodiments.

FIG. 1B illustrates a stacked die memory device in accordance with some example embodiments.

FIG. 2 illustrates two dies in a stacked die memory device in accordance with some example embodiments.

FIG. 3 illustrates an interconnect pillar in accordance with some example embodiments.

FIG. 4 illustrates another interconnect pillar in accordance with some example embodiments.

FIG. 5 illustrates a major surface of a die in accordance with some example embodiments.

FIG. 6A illustrates a stage of manufacture of a semiconductor device in accordance with some example embodiments.

FIG. 6B illustrates a portion of a phototool in accordance with some example embodiments.

FIG. 6C illustrates another portion of a phototool in accordance with some example embodiments.

FIG. 7 illustrates another stage of manufacture of a semiconductor device in accordance with some example embodiments.

FIG. 8 illustrates another stage of manufacture of a semiconductor device in accordance with some example embodiments.

FIG. 9 illustrates an example method flow diagram in accordance with other example embodiments.

FIG. 10 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

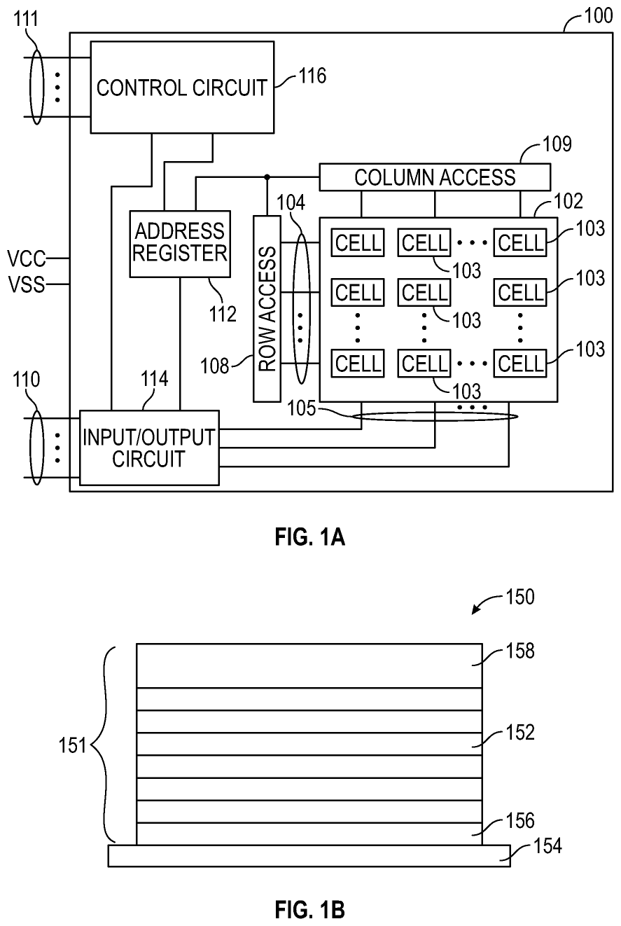

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

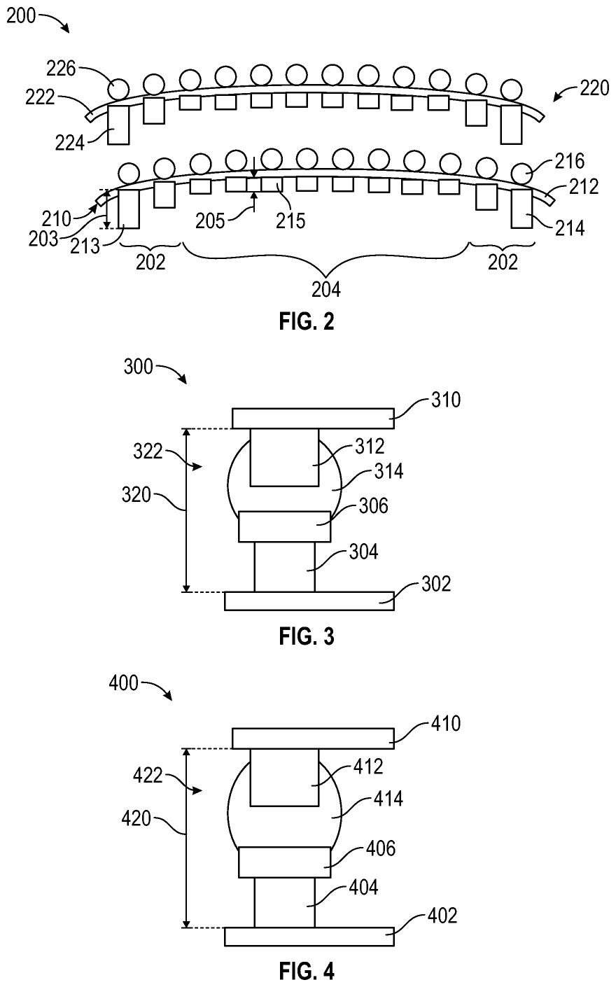

Memory cells 103 and other circuits 114, 116, etc. may include transistors and utilize methods as described in more detail in FIGS. 2-7. In one example, memory arrays 102 include NAND storage array, and peripheral circuits such as circuits 114, 116, 108, 109, etc. may include transistors as described in more detail in FIGS. 2-7.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100. Memory device 100 can include two or more stacked dies as described in more detail in examples below.

One of ordinary skill in the art will recognize that memory device 100 may include other elements, several of which are not shown in FIG. 1, so as not to obscure the example embodiments described herein.

FIG. 1B shows a semiconductor device 150 that includes a stack of semiconductor dies 151. In the example of FIG. 1B, the stack of semiconductor dies 151 are coupled to a circuit board 154, or other substrate. In one example, the stack of semiconductor dies 151 includes memory dies 152. In one example, the memory dies 152 include DRAM memory dies. In one example, the memory dies 152 include NAND memory dies. In one example, the stack of semiconductor dies 151 include a logic die and memory dies. In one example, a logic die 156 is located on a bottom of the stack of memory dies, although the invention is not so limited. In one example, multiple dies in the stack of semiconductor dies 151 are approximately the same thickness. In one example, a top die 158 is thicker than other dies in the stack of semiconductor dies 151.

FIG. 2 shows a first semiconductor die 210 and a second semiconductor die 220 aligned with the first semiconductor die 210 and positioned to be stacked with the first semiconductor die 210. The first semiconductor die 210 is shown in a warped condition that is exaggerated for illustration purposes. The second semiconductor die 220 is also shown in an exaggerated warped condition. In the example of FIG. 2, both dies are warped in a simple “frown” geometry, although the invention is not so limited. Due to a number of factors, including but not limited to, different material choices, different material thicknesses, different processing conditions, etc. individual dies in a stack of dies may be warped in any number of different complex geometries. For example, a warpage profile can include both “frown” and “smile” components, and the warpage profile can include several different regions in a major plane of a die. In one example, a warpage geometry is predictable and can be mapped.

The first die 210 of FIG. 2 includes a silicon portion 212 having a periphery region 202 and an interior region 204. A first array of interconnect pillars 214 are shown on a bottom side of the first die 210. A second array of interconnect pillars 216 are also shown on a top side of the first die 210.

In the example of FIG. 2, one or more array 214, 216 includes more than one pillar height. In the example shown, pillar 213, located in the periphery region 202 includes a first height 203. Pillar 215, located in the interior region 204, includes a second height 205 that is shorter than the first height 203.

The second die 220 of FIG. 2 includes a silicon portion 222 having a periphery region 202 and an interior region 204. A third array of interconnect pillars 224 are shown on a bottom side of the second die 220. A fourth array of interconnect pillars 226 are also shown on a top side of the second die 220.

Within a stack of dies similar to stack 151 of FIG. 1B, different die warpage conditions may exist that vary from die to die in the stack. In one example, pillars are longer adjacent to a periphery of the die, and shorter at an interior of the die to accommodate die warpage conditions in a middle of a stack. In one example, a pillar height distribution across a given die in a stack is mapped to a known warpage profile. In such an example, the pillar height distribution is designed to map to an adjacent die. In one example, a pillar height distribution is mapped to a known warpage profile that combines warpage of two adjacent dies in a stack.

In one example, a known warpage profile is evidenced by a warpage profile being similar across a number of examples of manufactured product. If several of the same product include the same warpage profile and interconnect pillars of more than one pillar height to accommodate the same warpage profile, then the warpage profile can be considered to be predicable and known.

As noted above, each die 210, 220 in FIG. 2 includes an array of interconnect pillars on both a top side and a bottom side. For example, in FIG. 2, array 224 on the bottom side of die 220 is arranged to mate with array 216 on a top side of die 210. In one example, only one of the arrays of interconnect pillars (224, 216) includes more than one pillar height to improve matching of interconnect pillars between the first die 210 and the second die 220. In one example, both of the arrays of interconnect pillars (224, 216) include more than one pillar height to improve matching of interconnect pillars between the first die 210 and the second die 220. In one example, a pillar height distribution is mapped to a known warpage profile that combines warpage of the first die 210 and warpage of the second die 220.

As noted in discussion of the stack of dies 151 from FIG. 1B, some example stacks 151 include different types and thicknesses of dies. In one example different pillar height distributions are utilized at different die interfaces in the stack 151 to accommodate different conditions between different die types. For example, the logic die 156 may warp differently due to its location in the stack 151 and/or its different arrangement of components on the logic die 156 as compared to other memory dies 152. Also, the top die 158 may warp differently due to its location in the stack 151 and/or its different thickness from other dies such as memory dies 152 and logic die 156.

FIG. 3 shows a pillar interface 300 between a first die 302 and a second die 310. The first die 302 includes a first conductor pillar 304 such as a copper pillar. In selected examples a second layer 306 such as a nickel layer may be included. The second die 310 also includes a second conductor pillar 312 such as a copper pillar. A solder bump 314 is shown joining the second conductor pillar 312 and the nickel layer 306. The combined components 312, 314, 306, and 304 make up a joint 322 that has a combined height 320. Heights of any of the components 312, 314, 306, and 304 can be varied across a die to provide pillar height distributions.

FIG. 4 shows another example of a pillar interface 400 between a first die 402 and a second die 410. Similar to FIG. 3, in FIG. 4, the first die 402 includes a first conductor pillar 404 such as a copper pillar. In selected examples a second layer 406 such as a nickel layer may be included. The second die 410 also includes a second conductor pillar 412 such as a copper pillar. A solder bump 414 is shown joining the second conductor pillar 412 and the nickel layer 406. The combined components 412, 414, 406, and 404 make up a joint 422 that has a combined height 420. In FIG. 4, the solder bump 414 is taller to provide the pillar height distribution. In one example, before forming the joint 422, the solder bump 414 may be coupled to the second conductor pillar 412, and provide a combined pillar height (412 and 414) that can be varied to provide a pillar height distribution on just the second die 410.

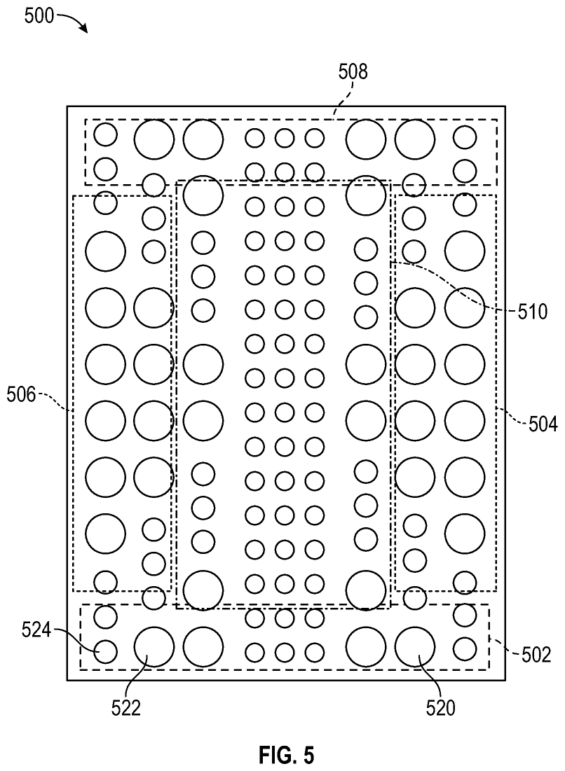

FIG. 5 shows a major surface of a die 500. The die 500 is shown including a number of example zones. A bottom zone 502, a right size zone 504, a left side zone 506 a top zone 508, and an interior zone 510 are shown in dashed lines. In one example, pillar heights are the same within a given zone, but pillar heights are different from zone to zone. In other examples, pillar heights may vary continuously across a die as determined by a known die warpage. As shown in FIG. 5, more than one pillar diameter may also be included. For example, pillar 522 has a larger diameter than pillar 524.

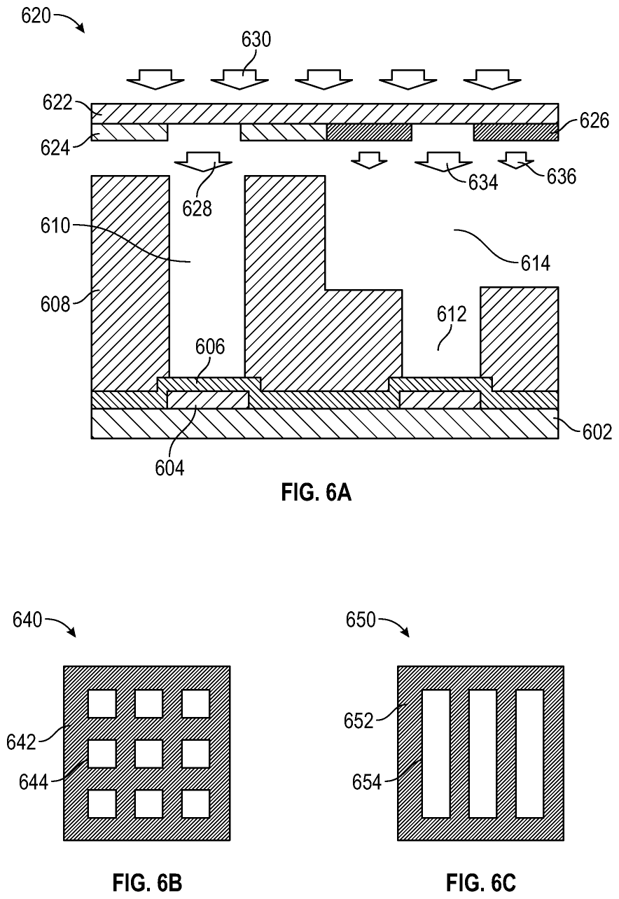

FIGS. 6-8 illustrate selected stages in manufacturing pillars of different heights as discussed above. FIG. 6A shows a die 602 with a number of electrical contacts 604. In one example, an intermediate conductor layer 606, such as a passivation layer, is included. A photoresist layer 608 is shown over the electrical contacts 604. A phototool 620 is shown above the die 602. A transparent core 622 is shown, with an opaque coating 624 in selected regions, and transparent openings 628 in other regions. A partially opaque coating 626 is also shown on the phototool 620. In one example, the opaque coating 624 includes chrome, and the partially opaque coating 626 includes a patterned chrome with a pattern of opaque and transparent portions to provide a partially opaque property. Examples of the pattern of opaque and transparent portions are discussed in more detail in FIGS. 6B and 6C below.

Arrows 630 indicate incoming radiation such as light, to interact with the photoresist layer 608. In transparent regions 628, substantially all incoming radiation passes through the phototool 620 as indicated by arrows 634. In opaque coating 624 regions, all incoming radiation is blocked. In partially opaque coating 626 regions, only a portion of incoming radiation passes through the phototool 620 as indicated by arrows 636.

FIG. 6B shows a pattern 640 of opaque 642 and transparent 644 portions to provide a partially opaque property. By controlling a ratio of opaque 642 and transparent 644 portions, an amount of radiation 636 that is allowed to pass through the partially opaque coating is controlled. FIG. 6C shows another example of a pattern 650 of opaque 652 and transparent 654 portions. The pattern 650 includes a larger percentage of transparent 654 portions compared to opaque 652 portions. As a result, the pattern 650 will pass more radiation through a phototool than pattern 640, but still less radiation than through an unpatterned transparent region 628.

In transparent regions 628 the photoresist 608 is completely reacted by a first amount of radiation that passes through the transparent region 628. As a result, a narrow opening 610 is formed with steep parallel sidewalls. Likewise a second narrow opening 612 is formed because it is located directly below a transparent region 634. In region 614, that is directly adjacent to opening 612, a second amount of radiation less than the first amount passes through the phototool due to the partially opaque coating 626. The second amount of radiation forms a gradated opening (region 614) in the photoresist 608 around opening 612.

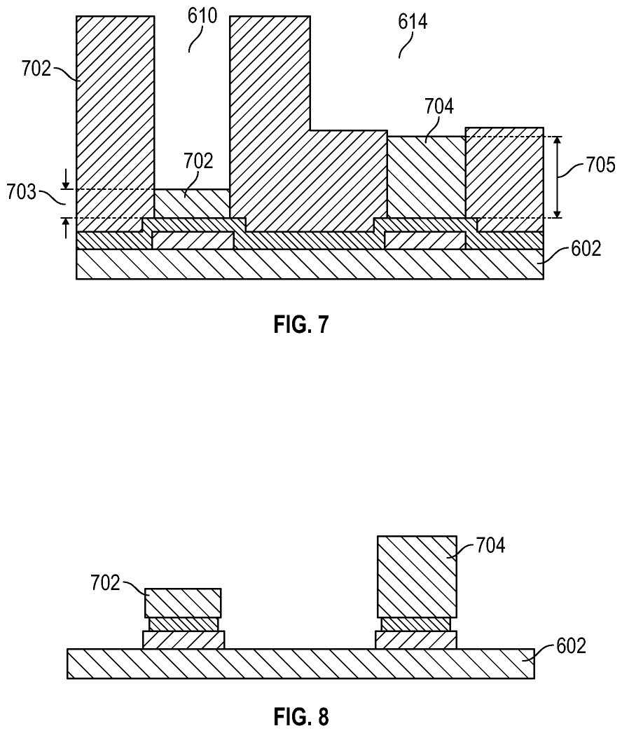

FIG. 7 shows the die 602 after the photoresist layer 608 has been exposed as described above. In FIG. 7, a plating operation is further performed to deposit a conductor material to form pillars as described in examples above. First pillar 702 and second pillar 704 are shown having different heights. Pillar 702 has a height 703 that is shorter than height 705 of pillar 704. Examples of conductor materials for pillars include, but are not limited to, copper, nickel, solder, or other conductors that form pillars. In one example, a chemical plating operation is used to form pillars 702, 704. Because the gradated opening (region 614) is wider than opening 610, plating molecules will reach a bottom within opening 612 more quickly. This results in pillar 704 being taller than pillar 702. FIG. 8 shows the die 602 with the photoresist 608 removed and only pillars 702, 704 remaining.

In one example, chemical plating is used, and the dated opening (region 614) operates as described above. Other plating operations are also within the scope of the invention, provided that they selectively deposit at different speeds depending on a width of a gradated opening such as opening 614. The example of FIG. 7 shows only a gradated opening and a non-gradated opening. One of ordinary skill in the art, having the benefit of the present disclosure, will recognize that many different gradations of openings are possible, and any number of different pillar heights can be achieved with a single phototool as described.

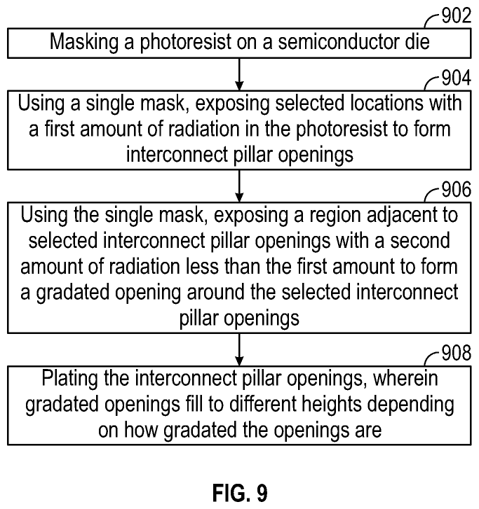

FIG. 9 shows a flow diagram of one example method of manufacture. In operation 902 a photoresist is masked on a semiconductor die. IN operation 904, selected locations are exposed using a single mask with a first amount of radiation in the photoresist to form interconnect pillar openings. In operation 906, a region is exposed adjacent to selected interconnect pillar openings, using the single mask, with a second amount of radiation less than the first amount to form a gradated opening around the selected interconnect pillar openings. In operation 908, the interconnect pillar openings are plated, wherein gradated openings fill to different heights depending on how gradated the openings are.

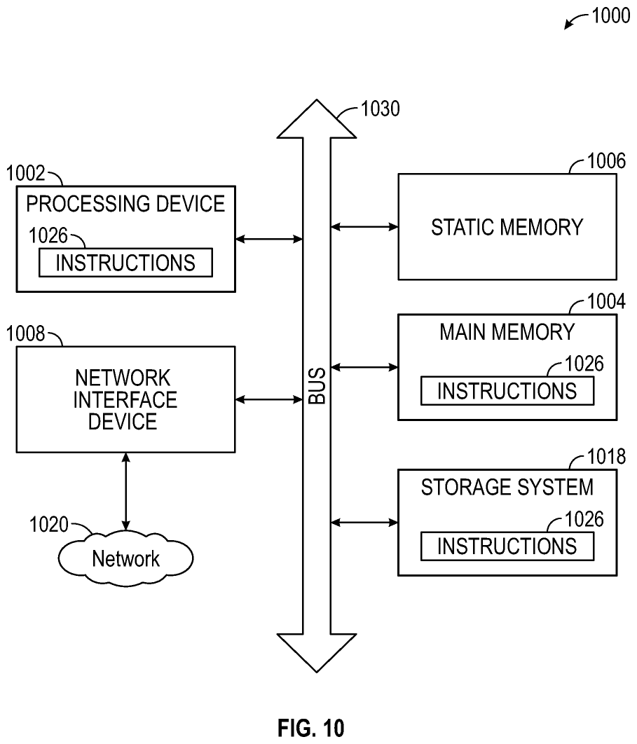

FIG. 10 illustrates a block diagram of an example machine (e.g., a host system) 1000 which may include one or more transistors, memory devices and/or memory systems as described above. Machine 1000 may include one or more stacked dies having interconnect pillars as described in examples above.

In alternative embodiments, the machine 1000 may operate as a standalone device or may be connected (e.g., networked) to other machines. In a networked deployment, the machine 1000 may operate in the capacity of a server machine, a client machine, or both in server-client network environments. In an example, the machine 1000 may act as a peer machine in peer-to-peer (P2P) (or other distributed) network environment. The machine 1000 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 1000 may include a processing device 1002 (e.g., a hardware processor, a central processing unit (CPU), a graphics processing unit (GPU), a hardware processor core, or any combination thereof, etc.), a main memory 1004 (e.g., read-only memory (ROM), dynamic random-access memory (DRAM) such as synchronous DRAM (SDRAM) or Rambus DRAM (RDRAM), etc.), a static memory 1006 (e.g., static random-access memory (SRAM), etc.), and a storage system 1018, some or all of which may communicate with each other via a communication interface (e.g., a bus) 1030. In one example, the main memory 1004 includes one or more memory devices as described in examples above.

The processing device 1002 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 1002 can also be one or more special-purpose processing devices such as an application specific integrated circuit (ASIC), a field programmable gate array (FPGA), a digital signal processor (DSP), network processor, or the like. The processing device 1002 can be configured to execute instructions 1026 for performing the operations and steps discussed herein. The computer system 1000 can further include a network interface device 1008 to communicate over a network 1020.

The storage system 1018 can include a machine-readable storage medium (also known as a computer-readable medium) on which is stored one or more sets of instructions 1026 or software embodying any one or more of the methodologies or functions described herein. The instructions 1026 can also reside, completely or at least partially, within the main memory 1004 or within the processing device 1002 during execution thereof by the computer system 1000, the main memory 1004 and the processing device 1002 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 1000 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 1000 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 1026 (e.g., software, programs, an operating system (OS), etc.) or other data are stored on the storage system 1018 can be accessed by the main memory 1004 for use by the processing device 1002. The main memory 1004 (e.g., DRAM) is typically fast, but volatile, and thus a different type of storage than the storage system 1018 (e.g., an SSD), which is suitable for long-term storage, including while in an “off” condition. The instructions 1026 or data in use by a user or the machine 1000 are typically loaded in the main memory 1004 for use by the processing device 1002. When the main memory 1004 is full, virtual space from the storage system 1018 can be allocated to supplement the main memory 1004; however, because the storage system 1018 device is typically slower than the main memory 1004, and write speeds are typically at least twice as slow as read speeds, use of virtual memory can greatly reduce user experience due to storage system latency (in contrast to the main memory 1004, e.g., DRAM). Further, use of the storage system 1018 for virtual memory can greatly reduce the usable lifespan of the storage system 1018.

The instructions 1024 may further be transmitted or received over a network 1020 using a transmission medium via the network interface device 1008 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 1008 may include one or more physical jacks (e.g., Ethernet, coaxial, or phone jacks) or one or more antennas to connect to the network 1020. In an example, the network interface device 1008 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 1000, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMS), read only memories (ROMs), and the like.

To better illustrate the method and apparatuses disclosed herein, a non-limiting list of embodiments is provided here:

Example 1 is a semiconductor device. The semiconductor device includes a first semiconductor die, and a second semiconductor die stacked with the first semiconductor die and electrically connected to the first semiconductor die by an array of interconnect pillars, wherein the array of interconnect pillars includes more than one pillar height.

In Example 2, the semiconductor device of Example 1 optionally includes wherein the array of interconnect pillars includes pillars that are taller adjacent to a periphery of the die, and shorter at an interior of the die.

In Example 3, the semiconductor device of any one of Examples 1-2 optionally includes wherein a pillar height distribution is mapped to a known warpage profile of either the first die or the second die.

In Example 4, the semiconductor device of any one of Examples 1-3 optionally includes wherein a pillar height distribution is mapped to a known warpage profile that combines warpage of the first die and warpage of the second die.

In Example 5, the semiconductor device of any one of Examples 1˜4 optionally includes wherein the array of interconnect pillars includes pillars extending down from the first die and up from the second die, and wherein heights of pillars extending down and heights of pillars extending up complement each other.

In Example 6, the semiconductor device of any one of Examples 1-5 optionally includes wherein the array of interconnect pillars includes copper.

In Example 7, the semiconductor device of any one of Examples 1-6 optionally includes wherein the array of interconnect pillars includes nickel on copper.

In Example 8, the semiconductor device of any one of Examples 1-7 optionally includes wherein the array of interconnect pillars includes solder.

Example 9 is a semiconductor device. The semiconductor device includes a stack of semiconductor dies, and an array of interconnect pillars at interfaces between dies in the stack, wherein one or more array of interconnect pillars includes more than one pillar height.

In Example 10, the semiconductor device of Example 9 optionally includes wherein pillar height arrangements are different between at least two different interfaces between dies in the stack.

In Example 11, the semiconductor device of any one of Examples 9-10 optionally includes wherein one of the dies in the stack of semiconductor dies includes a logic die.

In Example 12, the semiconductor device of any one of Examples 9-11 optionally includes wherein one of the dies in the stack of semiconductor dies includes a DRAM die.

In Example 13, the semiconductor device of any one of Examples 9-12 optionally includes wherein a top die in the stack of semiconductor dies is thicker than middle dies in the stack.

In Example 14, the semiconductor device of any one of Examples 9-13 optionally includes wherein pillars in a single given array of interconnect pillars at a given interface include different diameters.

Example 15 is a method. The method includes masking a photoresist on a semiconductor die, using a single mask, exposing selected locations with a first amount of radiation in the photoresist to form interconnect pillar openings, using the single mask, exposing a region adjacent to selected interconnect pillar openings with a second amount of radiation less than the first amount to form a gradated opening around the selected interconnect pillar openings, and plating the interconnect pillar openings, wherein gradated openings fill to different heights depending on how gradated the openings are.

In Example 16, the method of Example 15 optionally includes wherein exposing a region adjacent to selected interconnect pillar openings with a second amount of radiation includes exposing using a second region of the single mask that is only partially opaque.

In Example 17, the method of any one of Examples 15-16 optionally includes wherein using a second region of the single mask that is only partially opaque includes using a second region of the single mask that includes a pattern of opaque and transparent portions to provide a partially opaque property.

In Example 18, the method of any one of Examples 15-17 optionally includes wherein using a second region of the single mask that includes a pattern of opaque and transparent portions includes using a pattern of chrome plating to provide the opaque and transparent portions.

In Example 19, the method of any one of Examples 15-18 optionally includes wherein plating the interconnect pillar openings includes chemical plating.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor device, comprising:
a first semiconductor die; and
a second semiconductor die stacked with the first semiconductor die and electrically connected to the first semiconductor die by an array of interconnect pillars;
wherein the array of interconnect pillars includes more than one pillar height.

2. The semiconductor device of claim 1, wherein the array of interconnect pillars includes pillars that are taller adjacent to a periphery of the die, and shorter at an interior of the die.

3. The semiconductor device of claim 1, wherein a pillar height distribution is mapped to a known warpage profile of either the first die or the second die.

4. The semiconductor device of claim 1, wherein a pillar height distribution is mapped to a known warpage profile that combines warpage of the first die and warpage of the second die.

5. The semiconductor device of claim 1, wherein the array of interconnect pillars includes pillars extending down from the first die and up from the second die, and wherein heights of pillars extending down and heights of pillars extending up complement each other.

6. The semiconductor device of claim 1, wherein the array of interconnect pillars includes copper.

7. The semiconductor device of claim 1, wherein the array of interconnect pillars includes nickel on copper.

8. The semiconductor device of claim 1, wherein the array of interconnect pillars includes solder.

9. A semiconductor device, comprising:
a stack of semiconductor dies; and
an array of interconnect pillars at interfaces between dies in the stack;
wherein one or more array of interconnect pillars includes more than one pillar height.

10. The semiconductor device of claim 9, wherein pillar height arrangements are different between at least two different interfaces between dies in the stack.

11. The semiconductor device of claim 9, wherein one of the dies in the stack of semiconductor dies includes a logic die.

12. The semiconductor device of claim 9, wherein one of the dies in the stack of semiconductor dies includes a DRAM die.

13. The semiconductor device of claim 9, wherein a top die in the stack of semiconductor dies is thicker than middle dies in the stack.

14. The semiconductor device of claim 9, wherein pillars in a single given array of interconnect pillars at a given interface include different diameters.

15. A method, comprising:
masking a photoresist on a semiconductor die;
using a single mask, exposing selected locations with a first amount of radiation in the photoresist to form interconnect pillar openings;
using the single mask, exposing a region adjacent to selected interconnect pillar openings with a second amount of radiation less than the first amount to form a gradated opening around the selected interconnect pillar openings; and
plating the interconnect pillar openings, wherein gradated openings fill to different heights depending on how gradated the openings are.

16. The method of claim 15, wherein exposing a region adjacent to selected interconnect pillar openings with a second amount of radiation includes exposing using a second region of the single mask that is only partially opaque.

17. The method of claim 16, wherein using a second region of the single mask that is only partially opaque includes using a second region of the single mask that includes a pattern of opaque and transparent portions to provide a partially opaque property.

18. The method of claim 17, wherein using a second region of the single mask that includes a pattern of opaque and transparent portions includes using a pattern of chrome plating to provide the opaque and transparent portions.

19. The method of claim 15, wherein plating the interconnect pillar openings includes chemical plating.
